(19) United States
(12) Patent Application Publication
(10) Pub. No.: US 2025/0301829 A1
(43) Pub. Date: Sep. 25, 2025

(54) INFRARED LED ELEMENT

(71) Applicant: Ushio Denki Kabushiki Kaisha, Tokyo (JP)

(72) Inventor: Kazuyuki IIZUKA, Tokyo (JP)

(73) Assignee: Ushio Denki Kabushiki Kaisha, Tokyo (JP)

(21) Appl. No.: 19/076,116

(22) Filed: Mar. 11, 2025

(30) Foreign Application Priority Data
Mar. 19, 2024 (JP) 2024-043055

(51) Int. Cl. H10H 20/821; H10H 20/01; H10H 20/812; H10H 20/816; H10H 20/824

(52) U.S. Cl. CPC H10H 20/821; H10H 20/0133; H10H 20/812; H10H 20/8162; H10H 20/8242

(57) ABSTRACT

An infrared light-emitting diode (LED) element is capable of emitting infrared light having a peak wavelength of 1350 nm to 2000 nm and includes: a first stacked body including a first semiconductor that exhibits a first conductivity type, and an intermediate layer having a thickness of 15 nm or more; an active layer disposed on or over the intermediate layer of the first stacked body; and a second stacked body including a second semiconductor layer that exhibits a second conductivity type different from at least the first conductivity type and is disposed on or over the active layer. A relationship Eₐ<Eₘ<Eₚ holds, where Eₐ represents the band gap energy of the active layer, Eₘ represents the band gap energy of the intermediate layer, and Eₚ represents the band gap energy of the first semiconductor layer.

### CROSS-REFERENCE TO RELATED APPLICATION

The present invention claims the benefit of priority to Japanese Patent Application 2024-043055 with the Japanese Patent Office, the entire contents of which are incorporated herein by reference in its entirety.

### BACKGROUND OF THE INVENTION

### Field of the Invention

The present invention relates to an infrared light-emitting diode (LED) element, and particularly relates to an infrared LED element having an emission wavelength of 1350 nm or more.

### Description of the Related Art

In recent years, semiconductor light-emitting elements having an emission wavelength in an infrared region of wavelengths of 1000 nm or more have been used for a wide variety of applications, such as surveillance and monitoring cameras, gas detectors, medical sensors, and industrial equipment.

A semiconductor light-emitting element having an emission wavelength of 1000 nm or more is generally manufactured through the following procedure. A semiconductor layer of a first conductivity type, an active layer (sometimes referred to as a “light-emitting layer”), and a semiconductor layer of a second conductivity type are epitaxially grown in sequence on an indium phosphide (InP) substrate that acts as a growth substrate, and then an electrode for current injection is formed on the semiconductor wafer. Thereafter, the semiconductor wafer is cut into a chip shape.

For example, as disclosed in Patent Document 1 below, an infrared LED element including an active layer and a cladding layer made of InP is known. Such a structure has a relatively simple configuration to achieve light emission of 1000 nm or more.

### PRIOR ART DOCUMENT

### Patent Document

Patent Document 1: JP-B1-6617218

### SUMMARY OF THE INVENTION

The present inventor has intensively studied improvement in light emission efficiency of an LED element having a light emission wavelength of 1000 nm or more, and resultantly found that there are the following problems.

For the LED element having a light emission wavelength of 1000 nm or more, the present inventor has confirmed a driving voltage (hereinafter sometimes referred to as a “forward voltage”) required for turning on the LED element. Then, the present inventor has noticed that the driving voltage required for turning on the LED element tends to be higher than a theoretical driving voltage as the emission wavelength becomes longer. Here, the theoretical forward voltage is a driving voltage derived based on the relationship between the energy E and the wavelength λ (E (eV)=hc/λ=1240/λ). This will be described in detail later in the section “DETAILED DESCRIPTION OF THE PREFERRED EMBODIMENT”.

An increase in the driving voltage can also cause heat generation in the LED element. The LED element has a characteristic that the light emission efficiency decreases according to the temperature when the LED element is turned on. Thus, it is extremely important to suppress an increase in the driving voltage.

Therefore, after finding the above issues, the present inventor has intensively studied factors that cause the driving voltage required for turning on the LED element to differ from the theoretical driving voltage. Furthermore, the present inventor has intensively studied how taking measures against the above factors leads to achieving an LED element that is turned on at a driving voltage close to a theoretical driving voltage, that is, at a lower driving voltage, compared to the conventional one.

In view of the above issues, an object of the present invention is to provide an infrared LED element that can be turned on with a lower driving voltage than the conventional one.

An infrared LED element of the present invention is an infrared LED element capable of emitting infrared light having a peak wavelength of 1350 nm to 2000 nm, the infrared LED element including: a first stacked body including a first semiconductor layer and an intermediate layer in a stacking direction, the first semiconductor layer exhibiting a first conductivity type that is one of n-type or p-type, the intermediate layer having a thickness of 15 nm or more; an active layer disposed on or over the intermediate layer of the first stacked body; and a second stacked body including a second semiconductor layer that exhibits a second conductivity type different from the first conductivity type and is disposed on or over the active layer. A relationship Eₐ<Eₘ<Eₚ holds, where Eₐ represents the band gap energy of the active layer, Eₘ represents the band gap energy of the intermediate layer, and Eₚ represents the band gap energy of the first semiconductor layer.

The present inventor has inferred that in the conventional LED element, the driving voltage required for turning on the LED element becomes higher than expected as the emission wavelength becomes longer due to the difference in band gap energy between the active layer and the cladding layer (this corresponds to the “first semiconductor layer” and the “second semiconductor layer” in the infrared LED element).

It is generally considered that a cladding layer included in a conventional infrared LED element preferably has a larger band gap to confine electrons in an active layer. Note that InP is generally used as a material of a cladding layer in an infrared LED element using an InP single-crystal substrate capable of emitting light having a peak wavelength of 1000 nm to 2000 nm.

Here, the band gap energy of the active layer decreases as the peak wavelength becomes longer. Therefore, the difference in band gap energy between the active layer and the cladding layer increases as the peak wavelength becomes longer. Then, the present inventor has estimated that in a portion where the band gap energy between the active layer and the cladding layer discontinuously changes, when the difference in the band gap energy becomes equal to or larger than a certain magnitude, a voltage drop in the portion becomes significant, and inferred that the voltage drop is a factor of an increase in the driving voltage.

Note that, as will be described in detail with reference to the drawings in the item of “DETAILED DESCRIPTION OF THE PREFERRED EMBODIMENT”, the present inventor has confirmed that the difference between theoretical and actual values of a driving voltage required for turning on an infrared LED element is larger for an infrared LED that emits light having a peak wavelength of 1350 nm or more (cf. FIG. 3A).

The present inventor who has inferred as described above has intensively studied to form an intermediate layer that satisfies the above relationship between the active layer and the cladding layer to suppress a voltage drop due to the difference in band gap energy between the active layer and the cladding layer. Then, the present inventor confirmed that, according to the infrared LED element having the above configuration, the driving voltage required for turning on the LED element is reduced compared to the conventional LED element, more specifically, the driving voltage approaches a theoretical driving voltage (cf. FIG. 3A).

Furthermore, the present inventor has also found, through accumulated trial production studies and the like, that the driving voltage significantly decreases when the thickness of the intermediate layer is 15 nm or more (cf. FIG. 3B).

In other words, according to the above configuration, an infrared LED element is achieved that can be turned on by applying a voltage closer to the theoretical driving voltage compared to the conventional one, that is, by a driving voltage lower than the conventional one.

In the infrared LED element, the active layer may be formed by stacking a well layer and a barrier layer, and a relationship Eₐ<E_{b}<Eₘ may hold, where E_{b} represents the band gap energy of the barrier layer is.

With the above configuration, in the infrared LED element, electrons and holes are confined in the well layer sandwiched between the barrier layers, so that electrons and holes are easily recombined in the active layer, and the light emission efficiency is improved.

In the infrared LED element, the intermediate layer may be a semiconductor layer having a dopant concentration of 2×10¹⁸/cm³ or less.

A general method conceivable for reducing the voltage drop in the portion where the band gap energy discontinuously changes is, for example, increasing the doping concentration near the interface where the band gap energy discontinuously changes to lower the electric resistance value. However, since the interface is also near the active layer, when the doping concentration is increased, a high concentration of doped impurity atoms may diffuse into the active layer to become a non-luminescent recombination center, and the luminous efficiency may decrease.

The present inventor has found, through accumulated trial production studies and the like, that the doping concentration is preferably 2×10¹⁸/cm³ or less, and more preferably 5×10¹⁷/cm³ or less, in consideration of the fact that the intermediate layer is disposed closer to the active layer than the first semiconductor layer.

Further, in the infrared LED element, the active layer may have a thickness of 30 nm or more.

According to research and development by developers, it has been found that in a light-emitting diode (LED), when the total thickness of the active layer is less than 30 nm, electrons introduced into the active layer cannot be sufficiently converted into light, causing a decrease in light emission efficiency, and that the efficiency significantly decreases, particularly when the current density increases. Therefore, in the infrared LED element subject to the present invention, the thickness of the active layer is preferably 30 nm or more, and more preferably 40 nm or more. Note that when the active layer has a quantum well structure formed by stacking well layers and barrier layers, the total thickness of the well layers corresponds to the “thickness of the active layer”

Further, in the infrared LED element, the first semiconductor layer may be a layer made of InP.

Further, in the infrared LED element, the active layer may be a layer made of GaInAsP.

Further, in the infrared LED element, the first stacked body may include an electron blocking layer made of AlInAs and disposed on or over the first semiconductor layer.

Further, in the infrared LED element, when a difference between the band gap energy Eₐ of the active layer and the band gap energy Eₚ of the first semiconductor layer is 100%, a difference between the band gap energy Eₐ of the active layer and the band gap energy Eₘ of the intermediate layer may be within a range of 30% to 60%.

According to the present invention, an infrared LED element that can be turned on with a lower driving voltage than the conventional one is achieved.

### BRIEF DESCRIPTION OF THE DRAWINGS

FIG. 1 is a cross-sectional view schematically illustrating a structure of an infrared LED element according to an embodiment;

FIG. 2A is a cross-sectional view for describing a step in a method of manufacturing the infrared LED element illustrated in FIG. 1;

FIG. 2B is a cross-sectional view for describing a step in the method of manufacturing the infrared LED element illustrated in FIG. 1;

FIG. 2C is a cross-sectional view for describing a step in the method of manufacturing the infrared LED element illustrated in FIG. 1;

FIG. 2D is a cross-sectional view for describing a step in the method of manufacturing the infrared LED element illustrated in FIG. 1;

FIG. 2E is a cross-sectional view for describing a step in the method of manufacturing the infrared LED element illustrated in FIG. 1;

FIG. 2F is a cross-sectional view for describing a step in the method of manufacturing the infrared LED element illustrated in FIG. 1;

FIG. 2G is a cross-sectional view for describing a step in the manufacturing method of the infrared LED element illustrated in FIG. 1;

FIG. 2H is a cross-sectional view for describing a step in the manufacturing method of the infrared LED element illustrated in FIG. 1;

FIG. 2I is a cross-sectional view for describing a step in the manufacturing method of the infrared LED element illustrated in FIG. 1;

FIG. 2J is a cross-sectional view for describing a step in the manufacturing method of the infrared LED element illustrated in FIG. 1;

FIG. 2K is a cross-sectional view for describing a step in the manufacturing method of the infrared LED element illustrated in FIG. 1;

FIG. 2L is a cross-sectional view for describing a step in the manufacturing method of the infrared LED element illustrated in FIG. 1;

FIG. 2M is a cross-sectional view for describing a step in the manufacturing method of the infrared LED element illustrated in FIG. 1;

FIG. 2N is a cross-sectional view for describing a step in the manufacturing method of the infrared LED element illustrated in FIG. 1;

FIG. 3A is a graph obtained by plotting the results of Verification Experiment 1;

FIG. 3B is a graph obtained by plotting the results of Verification Experiment 2;

FIG. 4 is a cross-sectional view schematically illustrating a structure of an infrared LED element according to another embodiment; and

FIG. 5 is a cross-sectional view schematically illustrating a structure of an infrared LED element according to another embodiment.

### DETAILED DESCRIPTION OF THE PREFERRED EMBODIMENT

Hereinafter, an infrared LED element according to the present invention will be described with reference to the drawings. Note that each of the following drawings concerning the infrared LED element is schematically illustrated, and the dimensional ratio and the number in the drawings do not necessarily coincide with the actual dimensional ratio and the actual number.

In the present specification, the expression “a layer B is disposed on or over a layer A” is intended to include a case where the layer B is formed on the surface of the layer A with a thin film interposed therebetween, as well as a case where the layer B is formed directly on the surface of the layer A. Note that the “thin film” referred to herein may indicate a layer having a film thickness of 50 nm or less and preferably a layer having a film thickness of 10 nm or less.

In the present specification, the expression “the layer B is disposed on or over the layer A” is used as a concept including a case where the layer B is located above the layer A when the placement position of the infrared LED element is rotated. That is, the above expression is not an expression limiting the upper side in a state where the infrared LED element is disposed in a certain direction, but an expression suggesting that the layer A and the layer B are sequentially arranged in a first direction that is a stacking direction.

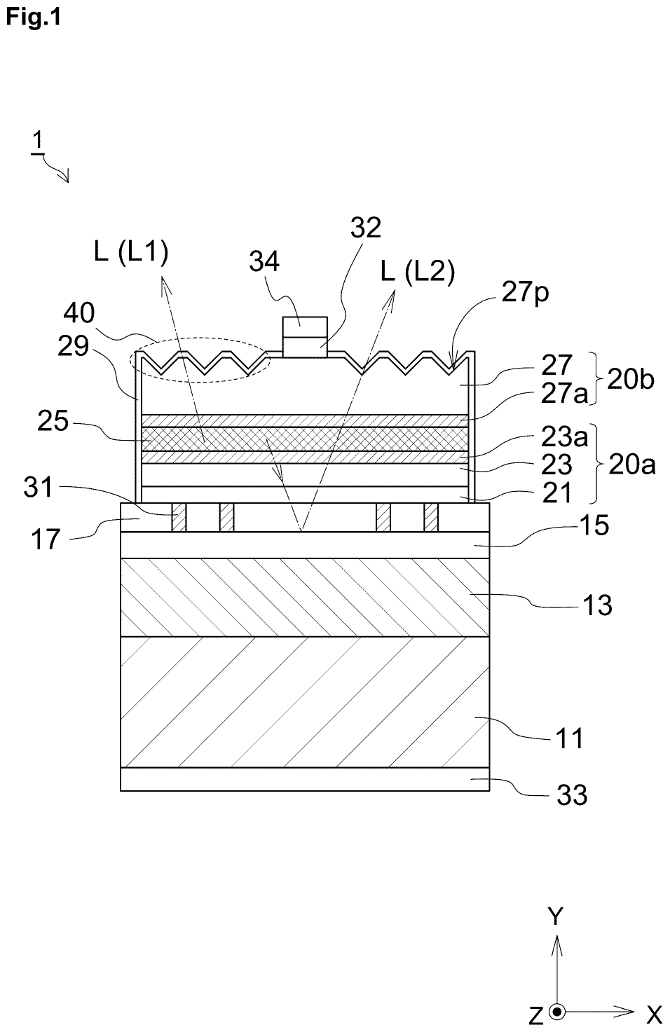

FIG. 1 is a cross-sectional view schematically illustrating a structure of an infrared LED element according to the present embodiment. In the description given hereinafter, reference is made as appropriate to an XYZ coordinate system added to FIG. 1.

In the following description, in the case of distinguishing whether the direction is positive or negative, the positive or negative symbol is added, such as the “+X direction” or the “−X direction”. When it is not necessary to make a distinction between positive and negative to express a direction, the direction is simply described as “X direction”. That is, when the direction is simply described as “X direction” herein, both “+X direction” and “−X direction” are included. The same applies to the Y direction and the Z direction. Note that, in the present embodiment, “the layer B is disposed on or over the layer A” will be described assuming that the layer B is disposed on the +Y side of the layer A.

In an infrared LED element 1, infrared light L is generated in an active layer 25 to be described later. More specifically, as illustrated in FIG. 1, the infrared light L (L1, L2) is extracted in the +Y direction with respect to the active layer 25. The infrared light L has a peak wavelength of 1350 nm to 2000 nm.

### [Element Structure]

The structure of the infrared LED element 1 will now be described in detail.

### (Support Substrate 11)

A support substrate 11 includes, for example, a semiconductor such as silicon (Si) or germanium (Ge), or a metal material such as copper (Cu) or copper-tungsten (CuW). When made of a semiconductor, the support substrate 11 may be highly doped with a dopant so as to exhibit electrical conductivity. As an example, the support substrate 11 is a Si substrate doped with boron (B) at a dopant concentration of 1×10¹⁹/cm³ or more and having a resistivity of 10 mΩ·cm or less. As the dopant, for example, phosphorus (P), arsenic (As), antimony (Sb), or the like can be used in addition to B. From the viewpoint of achieving both high heat dissipation and low manufacturing cost, the support substrate 11 is preferably n Si substrate.

The thickness (length in the Y direction) of the support substrate 11 is not particularly limited, but is, for example, 50 μm to 500 μm, and preferably 100 μm to 300 μm.

### (Metal Bonding Layer 13)

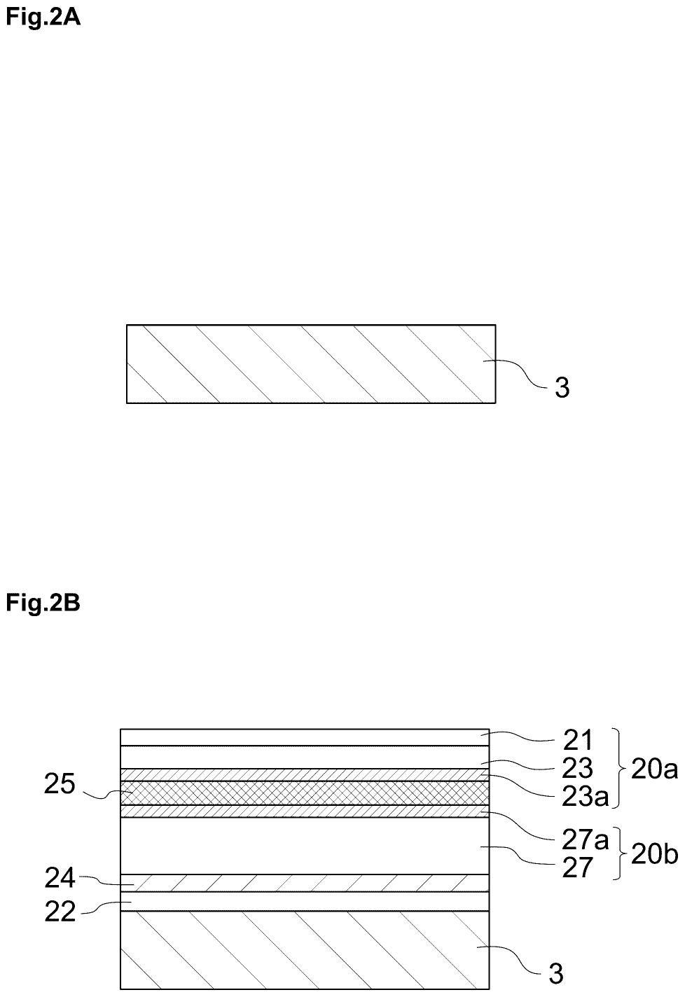

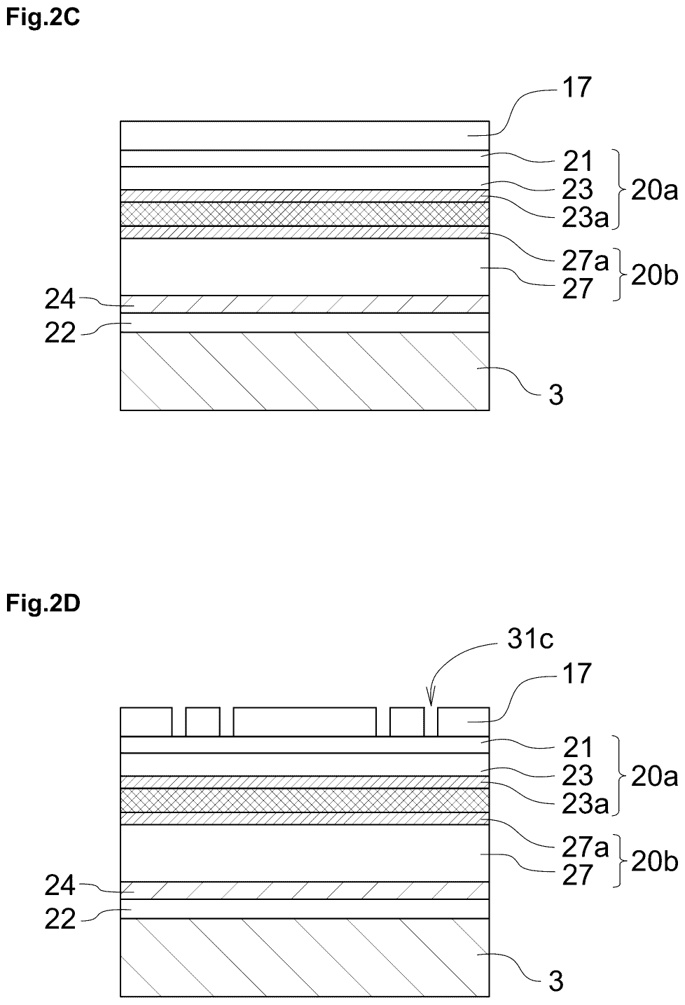

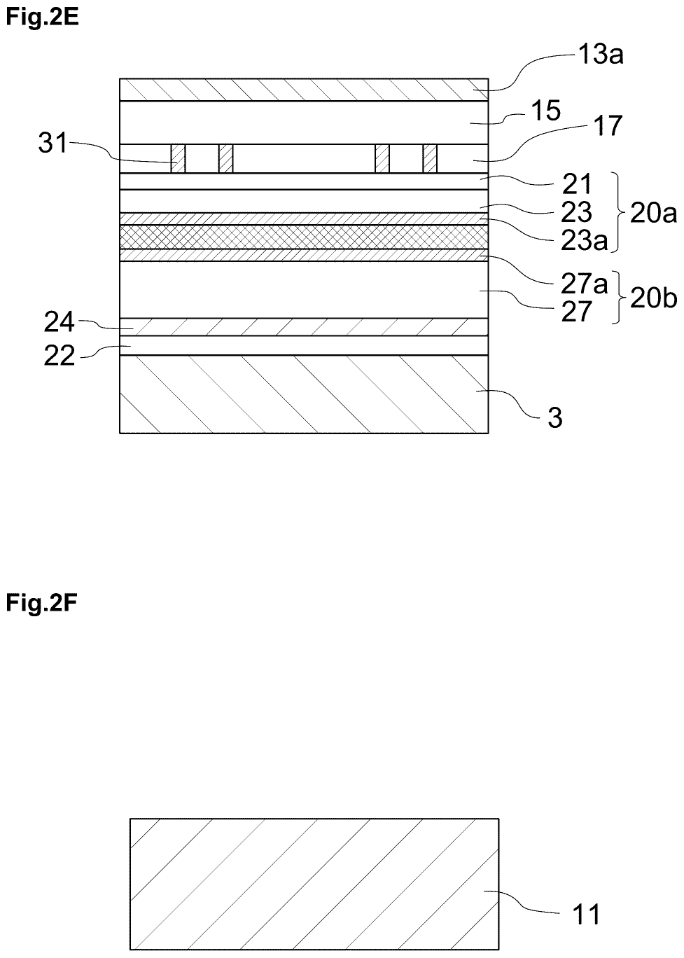

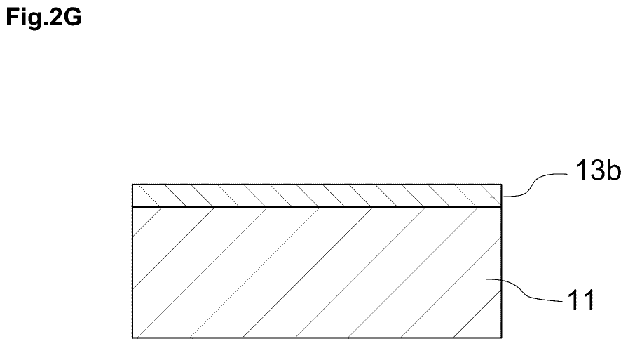

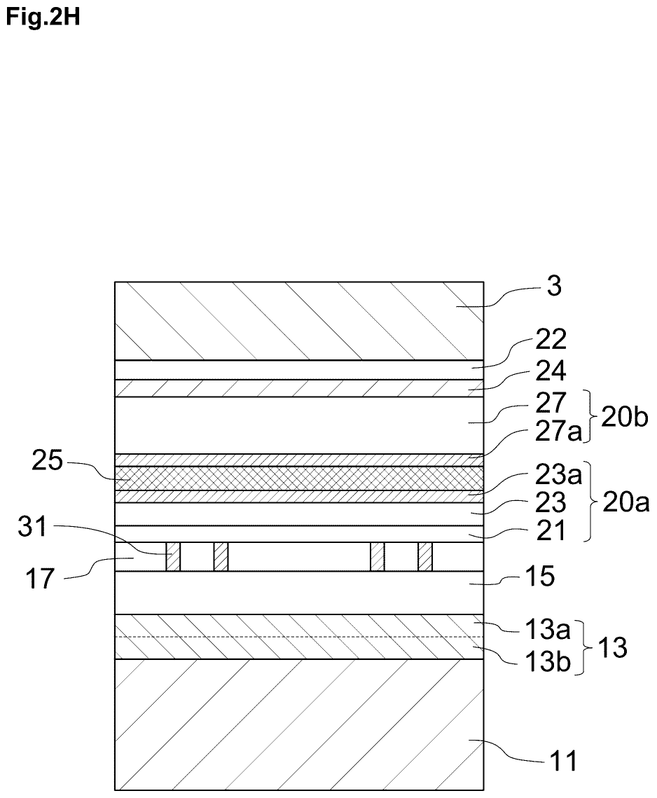

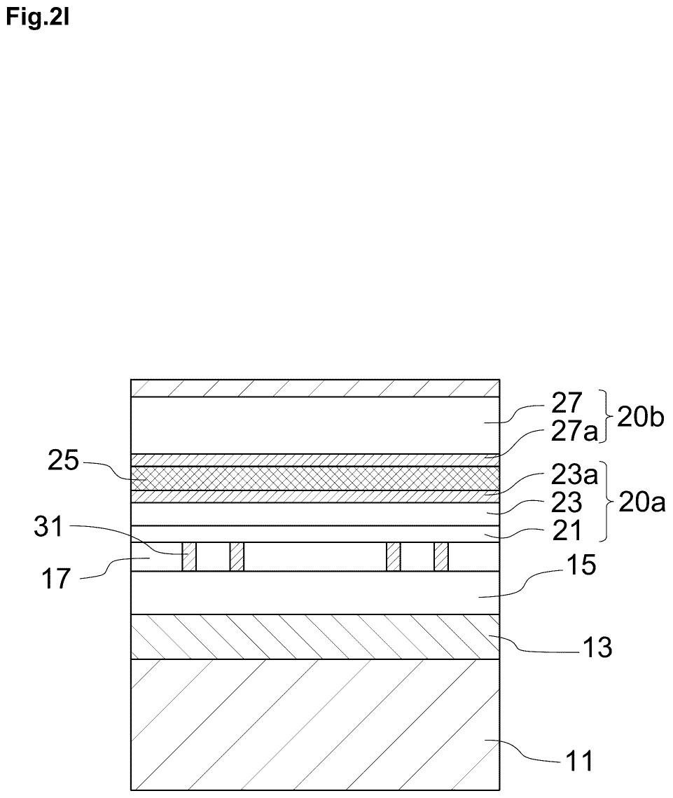

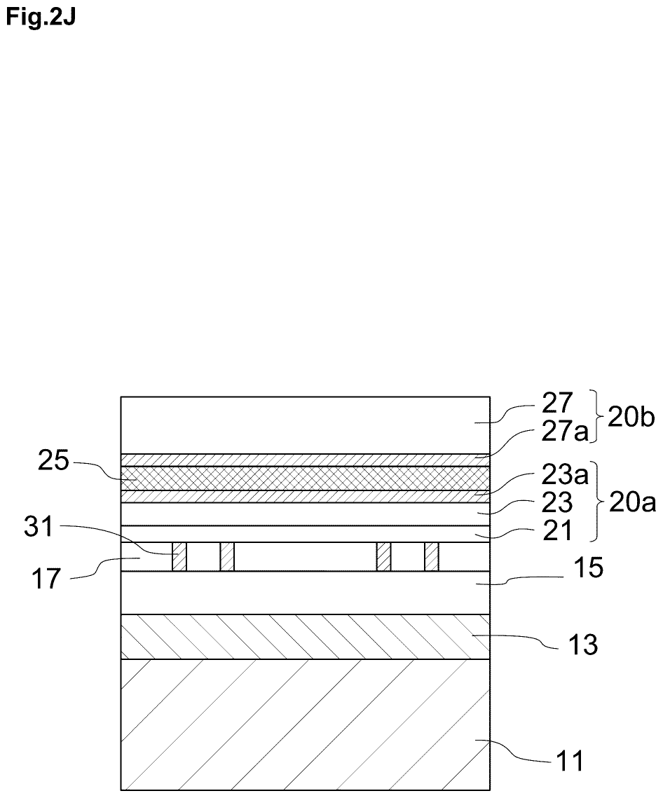

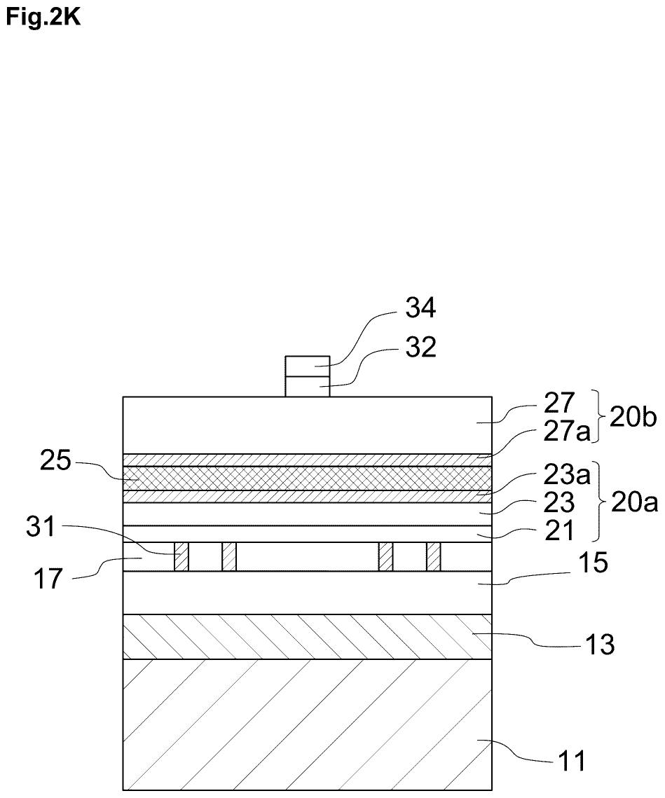

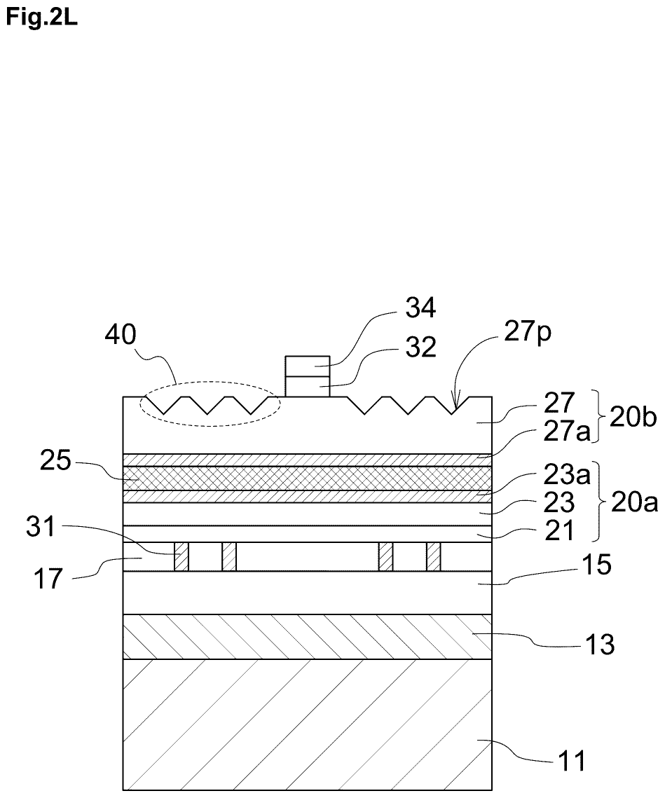

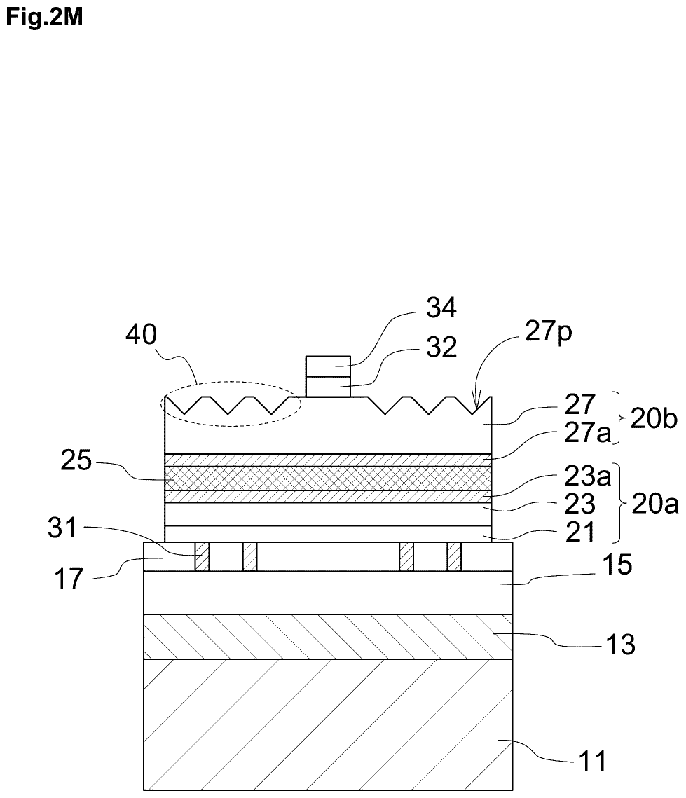

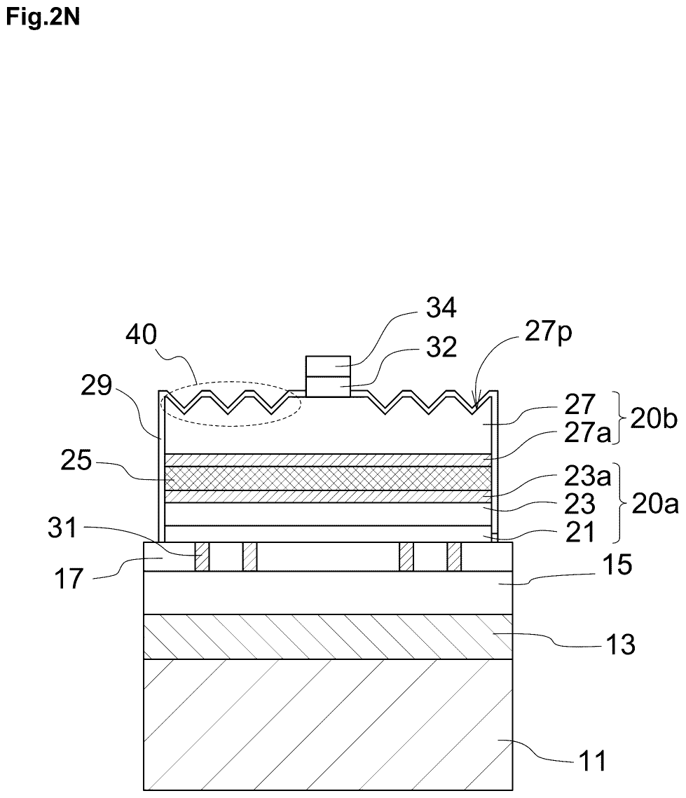

The infrared LED element 1 includes a metal bonding layer 13 disposed on the +Y side of the support substrate 11. The metal bonding layer 13 includes a low-melting solder material such as gold (Au), gold-zinc (Au—Zn), gold-tin (Au—Sn), gold-indium (Au—In), Au—Cu—Sn, Cu—Sn, palladium-tin (Pd—Sn), or Sn. As will be described later with reference to FIG. 2H, in step S8, the metal bonding layer 13 is used to bond a growth substrate 3 having a first stacked body 20a formed on the top surface to the support substrate 11. The thickness of the metal bonding layer 13 is not particularly limited, but is, for example, 0.5 μm to 5.0 μm, and preferably 1.0 μm to 3.0 μm.

Note that a barrier layer may be formed on the +Y side of the metal bonding layer 13. The barrier layer is provided in some cases for the purpose of suppressing diffusion of a solder material constituting the metal bonding layer 13. The material is not limited as long as such a function is achieved, but the barrier layer can be achieved by, for example, a material containing titanium (Ti), platinum (Pt), tungsten (W), molybdenum (Mo), nickel (Ni), or the like. As a more specific example, the barrier layer is a Ti/Pt stacked body, and may be configured by stacking multiple of the stacked bodies, such as Ti/Pt/Ti/Pt/Ti/Pt.

### (Reflective Layer 15)

The infrared LED element 1 of the present embodiment includes a reflective layer 15 disposed on the +Y side of the metal bonding layer 13.

The infrared light L generated in the active layer 25 includes infrared light L1 traveling toward the light-emitting surface side (+Y side) and infrared light L2 traveling toward the side opposite to the light-emitting surface (−Y side). The reflective layer 15 has a function of reflecting infrared light L2 traveling to the support substrate 11 side (−Y side) among the infrared light L generated in the active layer 25 and guiding the infrared light L2 toward the +Y side. The reflective layer 15 includes a conductive material and a material exhibiting high reflectance to the infrared light L. The reflectance of the reflective layer 15 with respect to the infrared light L is 50% or more, preferably 70% or more, more preferably 80% or more, and particularly preferably 90% or more.

When the peak wavelength of the infrared light L is 1350 nm to 2,000 nm, silver (Ag), an Ag alloy, Au, Al, Cu, or the like can be used as the material of the reflective layer 15. This material can be appropriately selected according to the wavelength of the infrared light L.

The thickness of the reflective layer 15 is not particularly limited, but is, for example, 0.1 μm to 2.0 μm inclusive, and preferably 0.3 μm to 1.0 μm inclusive.

Note that when the barrier layer as described above is formed between the reflective layer 15 and the metal bonding layer 13, a decrease in reflectance of the reflective layer 15 due to diffusion of the material constituting the metal bonding layer 13 toward the reflective layer 15 can be suppressed.

### (Insulating Layer 17)

The infrared LED element 1 illustrated in FIG. 1 includes an insulating layer 17 disposed on the +Y side of the reflective layer 15. The insulating layer 17 includes a material that exhibits electrical insulation and has high transparency to the infrared light L. The transmittance of the insulating layer 17 to the infrared light L is preferably 70% or more, more preferably 80% or more, and particularly preferably 90% or more.

When the peak wavelength of the infrared light L is 1350 nm to 2000 nm, SiO₂, SiN, aluminum oxide (Al₂O₃), zirconia oxide (ZrO), hydrofluoroolefin (HfO), magnesium oxide (MgO), or the like can be used as the material of the insulating layer 17. This material can be appropriately selected according to the wavelength of light generated in the active layer 25.

### (First Stacked Body 20a, Second Stacked Body 20b, Active Layer 25)

The infrared LED element 1 illustrated in FIG. 1 includes a first stacked body 20a disposed on the +Y side of the insulating layer 17, an active layer 25 disposed on or over the first stacked body 20a, and a second stacked body 20b disposed on or over the active layer 25. The first stacked body 20a is formed by, for example, stacking a first contact layer 21, a first cladding layer 23, and a first intermediate layer 23a in the Y direction. The second stacked body 20b is formed by, for example, stacking a second cladding layer 27 and a second intermediate layer 27a in the Y direction. Each layer (21, 23, 24, 25, 27, and 28) is made of a material that can be epitaxially grown while being lattice-matched to the growth substrate 3, which will be described later.

The entire thickness of the multilayer structure including the first stacked body 20a, the active layer 25, and the second stacked body 20b is 30 μm (30,000 nm) or less, and preferably 5 μm to 20 μm.

### <<First Contact Layer 21 and First Cladding Layer 23>>

In the present embodiment, the first contact layer 21 is made of any semiconductor material, but is preferably made of a group III-V semiconductor containing As, and is made of, for example, p-type InGaAs, p-type GaInAsP, or p-type GaAs. The thickness of the first contact layer 21 is not limited, but is, for example, 10 nm to 1000 nm, and preferably 50 nm to 500 nm. Further, the concentration of a p-type dopant in the first contact layer 21 is preferably 5×10¹⁷/cm³ to 3×10¹⁹/cm³, more preferably 1×10¹⁸/cm³ to 2×10¹⁹/cm³. Note that, in the first contact layer 21, at least a dopant concentration in a region in contact with an Au/Zn/Au layer to be described later is preferably 5×10¹⁸/cm³ or more from the viewpoint of obtaining a good ohmic contact.

In the present embodiment, the first cladding layer 23 is disposed on the +Y side of the first contact layer 21 and is made of, for example, p-type InP. The thickness of the first cladding layer 23 is not limited, but is, for example, 1000 nm to 10,000 nm, preferably 2000 nm to 5000 nm. The concentration of a p-type dopant in the first cladding layer 23, at a position apart from the active layer 25, preferably ranges from 1×10¹⁷/cm³ to 3×10¹⁸/cm³ inclusive, and more preferably ranges from 5×10¹⁷/cm³ to 3×10¹⁸/cm³ inclusive.

As the p-type dopant contained in the first contact layer 21 and the first cladding layer 23, a material such as Zn, Mg, or beryllium (Be), preferably Zn or Mg, and particularly preferably Zn can be used. In the present embodiment, the first contact layer 21, the first intermediate layer 23a, and the first cladding layer 23 correspond to a “first semiconductor layer”, and the p-type corresponds to a “first conductivity type”.

<<First Intermediate Layer 23a>>

In the present embodiment, the first intermediate layer 23a is disposed on the +Y side of the first cladding layer 23 and is a p-type doped layer, but may be undoped. The first intermediate layer 23a is configured as a layer satisfying the relationship Eₐ<Eₘ₁<Eₚ, where Eₐ represents the band gap energy of the active layer 25, Eₚ represents the band gap energy of the first cladding layer 23, and Eₘ₁ represents the band gap energy of the first intermediate layer 23a.

The thickness of the first intermediate layer 23a is not limited, but is preferably 15 nm or more, and more preferably 30 nm or more. Note that, from the viewpoint of confining electrons in the active layer 25, a band gap difference and a film thickness between the active layer 25 and the cladding layers (23 and 27) are required to some extent. In a range where the wavelength of emitted light is 1350 nm to 2000 nm, InP is generally employed as the cladding layer (23,27) because the band gap energy between the active layer 25 and the cladding layer is large. Therefore, when the band gap energy of the active layer 25 is Eₐ and the band gap energy of the cladding layers (23 and 27) is Eₚ, and the difference therebetween is 100%, a layer in which the band gap difference is 80% or more and the film thickness is 200 nm or more is recognized as the cladding layer.

The p-type dopant concentration of the first intermediate layer 23a is preferably 2×10¹⁸/cm³ or less, and more preferably 5×10¹⁷/cm³ or less to satisfy the relationship of band gap energy (Eₐ<Eₘ₁<Eₚ) described above.

When the difference between the band gap energy Eₐ of the active layer 25 and the band gap energy Eₚ of the first cladding layer 23 is 100%, the difference between the band gap energy Eₐ of the active layer 25 and the band gap energy Eₘ₁ of the first intermediate layer 23a is preferably within a range of 40% to 60%, and more preferably within a range of 45% to 55%.

The material of the first intermediate layer 23a is appropriately selected from materials that do not absorb the infrared light L generated in the active layer 25 and can be epitaxially grown while being lattice-matched to the growth substrate 3. When an InP substrate is employed as the growth substrate 3, InP, GaInAsP, AlGaInAs, or the like can be used as the material of the first intermediate layer 23a, but InP is preferable.

### <<Active Layer 25>>

In the present embodiment, the active layer 25 is disposed on the +Y side of the first cladding layer 23. The material of the active layer 25 is appropriately selected from materials that can generate light with a peak wavelength falling within a target wavelength range and can be epitaxially grown while being lattice-matched to the growth substrate 3.

When the infrared LED element 1 that emits infrared light L having a peak wavelength of 1350 nm to 2000 nm is manufactured, the active layer 25 may have a single-layer structure of GaInAsP, AlGaInAs, or InGaAs, or preferably has a multiple quantum well (MQW) structure that includes a well layer made of GaInAsP, AlGaInAs, or InGaAs and a barrier layer made of GaInAsP, AlGaInAs, InGaAs, or InP having band gap energy higher than that of the well layer. When the MQW structure is employed in the active layer 25, the structure is formed to satisfy the relationship Eₐ<E_{b}<Eₘ₁, where Eₐ represents the band gap energy of the active layer 25, Eₘ represents the band gap energy of the first intermediate layer 23a, and E_{b} represents the band gap energy of the barrier layer.

The thickness of the active layer 25 is preferably 30 nm or more, and more preferably 40 nm or more. More specifically, when the active layer 25 has a single layer structure, the thickness is preferably 30 nm to 2000 nm, and more preferably 50 nm to 1000 nm. When the active layer 25 has the MQW structure, the well layer and the barrier layer having a film thickness of 5 nm to 20 nm are stacked in a range of 2 cycles to 50 cycles, and the total thickness of all the well layers is preferably 30 nm or more, more preferably 40 nm or more.

The active layer 25 may be doped with an n-type or p-type dopant or may be undoped. When the active layer 25 is doped with the n-type dopant, the dopant may be, for example, Si.

### <<Second Cladding Layer 27>>

In the present embodiment, the second cladding layer 27 is disposed on the +Y side of the active layer 25 and is made of, for example, n-type InP. The second cladding layer 27 needs to have a certain film thickness and impurity concentration for the purpose of current dispersion. The thickness of the second cladding layer 27 is not limited, but is, for example, 2000 nm to 15000 nm, preferably 5000 nm to 10000 nm.

The concentration of the n-type dopant in the second cladding layer 27 is preferably 5×10¹⁷/cm³ or more, more preferably 1×10¹⁸/cm³ or more. Note that when the current dispersion and the like is also taken into consideration, a range of the concentration of the n-type dopant in the second cladding layer 27 is preferably 5×10¹⁷/cm³ to 1×10¹⁹/cm³, more preferably 1×10¹⁸/cm³ to 5×10¹⁸/cm³.

The material of the second cladding layer 27 is appropriately selected from materials that do not absorb the infrared light L generated in the active layer 25 and can be epitaxially grown while being lattice-matched to the growth substrate 3 (cf. FIG. 2B). When an InP substrate is employed as the growth substrate 3, InP, GaInAsP, AlGaInAs, or the like can be used as the material of the second cladding layer 27, but InP is preferable.

As the n-type impurity material doped in the second cladding layer 27, Sn, Si, S, Ge, Se, or the like can be used, and Si is particularly preferable. In the present embodiment, the second intermediate layer 27a and the second cladding layer 27 correspond to the “second semiconductor layer”, and the n-type corresponds to the “second conductivity type”.

As illustrated in FIG. 1, in the infrared LED element 1 of the present embodiment, an uneven portion 40 is formed on a +Y-side surface (hereinafter referred to as a “first surface 27p”) of the second cladding layer 27. The uneven portion 40 is schematically illustrated in a periodic shape in FIG. 1, but actually has a random uneven shape formed by dip treatment using an etching solution.

<<Second Intermediate Layer 27a>>

In the present embodiment, the second intermediate layer 27a is disposed on the −Y side of the second cladding layer 27 and is an n-type doped layer, but may be undoped. The second intermediate layer 27a is configured as a layer satisfying the relationship E_{q}>Eₘ2>Eₐ, where Eₐ represents the band gap energy of the active layer 25, E_{q} represents the band gap energy of the second cladding layer 27, and Eₘ₂ represents the band gap energy of the second intermediate layer 27a.

The thickness of the second intermediate layer 27a is not limited, but is preferably 15 nm or more, and more preferably 30 nm or more, similarly to the first intermediate layer 23a. The n-type dopant concentration of the second intermediate layer 27a is preferably 2×10¹⁸/cm³ or less, and more preferably 5×10¹⁷/cm³ or less to satisfy the relationship of the band gap energy (Eₐ<Eₘ<Eₚ) described above.

The material of the second intermediate layer 27a is appropriately selected from materials that do not absorb the infrared light L generated in the active layer 25 and can be epitaxially grown while being lattice-matched to the growth substrate 3. When an InP substrate is employed as the growth substrate 3, InP, GaInAsP, AlGaInAs, or the like can be used as the material of the second intermediate layer 27a, but InP is preferable.

### (Protection Film 29)

A protection film 29 is a film formed mainly for the purpose of protecting the exposed surface of the active layer 25. The material of the protection film 29 may be, for example, Si₃N₄, SiO₂, an intermediate material between Si₃N₄ and SiO₂, or the like. Since the Si₃N₄ film is more excellent in barrier effect against moisture than the SiO₂ film, the Si₃N₄ film is preferable as the protection film 29. For manufacturing convenience, the protection film 29 may be configured to cover the first surface 27p of the second stacked body, as illustrated in FIG. 1. When the refractive index at the wavelength λ of the infrared light L generated in the active layer 25 of the protection film 29 is n so that the light generated in the active layer 25 is efficiently extracted to the outside, the film thickness T of the protection film 29 preferably satisfies the relationship of T=λ/(4n) from the viewpoint of the antireflection effect.

### (Internal Electrode 31)

An infrared LED element 1 illustrated in FIG. 1 includes an internal electrode 31 formed in a through hole penetrating in the Y direction at a plurality of places of the insulating layer 17, and electrically connects the first semiconductor layer (21, 23) and the support substrate 11 via the reflective layer 15 and the metal bonding layer 13.

The internal electrode 31 in the present embodiment is made of a material capable of forming an ohmic contact with the first contact layer 21. Examples of the material of the internal electrode 31 include Au, Zn, Be, and alloys thereof.

### (Top-Side Electrode 32)

The infrared LED element 1 illustrated in FIG. 1 includes a top-side electrode 32 disposed on the top surface of second stacked body 20b. A plurality of top-side electrodes 32 are typically formed to extend in a predetermined direction on the XZ plane. As an example, the plurality of top-side electrodes 32 extend in the X direction and the Z direction along the side of the second stacked body 20b, and has a comb shape. However, the shape of the arrangement pattern of the top-side electrode 32 is optional, and may be, for example, a lattice shape or a spiral shape.

The top-side electrode 32 is formed over a wide range on the XZ plane while exposing the surface of the second cladding layer 27 located on the −Y side (directly or except for a part of the dielectric layer formed on the same surface). This enables the electric current flowing in the active layer 25 to expand in a direction parallel to the XZ plane direction and thus enables light emission in a wide range in the active layer 25.

The top-side electrode 32 includes, for example, a material such as AuGe/Ni/Au or AuGe, and may include a plurality of these materials.

### (Pad Electrode 34)

As illustrated in FIG. 1, the infrared LED element 1 includes a pad electrode 34 disposed on the top surface of a part of the top-side electrode 32. Note that, in FIG. 1, the pad electrode 34 is illustrated as being formed on the entire surface of the top-side electrode 32, but this is for convenience of illustration. In practice, the pad electrode 34 may be formed on a part of the surface of the top-side electrode 32 extending in the plane direction.

The pad electrode 34 includes, for example, Ti/Au, Ti/Pt/Au, or the like. This pad electrode 34 is provided for the purpose of ensuring a region to be brought into contact with a bonding wire for power supply, but it is optional whether the pad electrode 34 is provided in the present invention.

### (Back-Side Electrode 33)

The infrared LED element 1 illustrated in FIG. 1 includes a back-side electrode 33 disposed on the surface of the support substrate 11 on a side (−Y side) opposite to the first stacked body 20a. The back-side electrode 33 is brought into ohmic contact with the support substrate 11. The back-side electrode 33 includes, for example, a material such as Ti/Au or Ti/Pt/Au, and may contain two or more of these materials.

### [Manufacturing Method]

An example of a method for manufacturing the infrared LED element 1 described above will be described with reference to each of FIGS. 2A to 2M. FIGS. 2A to 2M are cross-sectional views in a step in the manufacturing process. Note that the order of the following procedures may be appropriately changed as long as the procedures do not affect the manufacture of the infrared LED element 1.

### (Step S1)

As illustrated in FIG. 2A, the growth substrate 3 is prepared. In the present embodiment, an InP substrate having a (001) plane as one main surface is suitably used as the growth substrate 3. An example of the thickness of the substrate is 370 μm, and the diameter of the main surface thereof is 2 inches. However, the thickness and size of the growth substrate 3 are set appropriately.

### (Step S2)

The growth substrate 3 is conveyed into, for example, a metal organic chemical vapor deposition (MOCVD) apparatus, and the buffer layer 22, the etching stop layer (ES layer) 24, the second cladding layer 27, the second intermediate layer 27a, the active layer 25, the first intermediate layer 23a, the first cladding layer 23, and the first contact layer 21 are sequentially epitaxially grown on the growth substrate 3 to form the first stacked body 20a, the active layer 25, and the second stacked body 20b (cf. FIG. 2B). In this step S2, the type and the flow rate of the raw material gas, the treatment time, the environmental temperature, and the like are appropriately adjusted according to the material of the layer to be grown or the film thickness.

Formation examples of the first stacked body 20a, the active layer 25, and the second stacked body 20b are as follows. First, n-type InP doped with Si is stacked on the growth substrate 3 with a predetermined film thickness (e.g., about 500 nm) to obtain the buffer layer 22. Next, a layer (here, the InGaAs layer) of a material different from that of the buffer layer 22 is stacked with a predetermined film thickness (e.g., about 200 nm) to obtain the ES layer 24. Thereafter, the second cladding layer 27, the second intermediate layer 27a, the active layer 25, the first intermediate layer 23a, the first cladding layer 23, and the first contact layer 21 are sequentially formed in a state where growth conditions are set to have the film thickness and composition described above.

As a detailed example, n-type InP using Si as a dopant is stacked in a film thickness of 7000 nm to obtain the second cladding layer 27. Next, n-type InP using Si as a dopant is stacked in a film thickness of 30 nm to obtain the second intermediate layer 27a.

Furthermore, InGaAsP is stacked with a film thickness of 900 nm to obtain the active layer 25. Here, the condition is such that the peak wavelength of the infrared light L emitted from the infrared LED element 1 is 1450 nm. However, as described above, the peak wavelength of the infrared light L can be adjusted within a range of 1350 nm to 2000 nm by adjusting the composition ratio of the materials constituting the active layer 25 or employing the MQW structure.

Thereafter, p-type InP using Zn as a dopant is stacked in a film thickness of 30 nm to obtain the first intermediate layer 23a, p-type InP using Zn as a dopant is stacked in a film thickness of 3000 nm to obtain the first cladding layer 23, and subsequently, p-type GaInAsP using Zn as a dopant is stacked in a film thickness of 200 nm to obtain the first contact layer 21.

### (Step S3)

The wafer on which the second stacked body 20b, the active layer 25, and the first stacked body 20a are formed on the growth substrate 3 is taken out from the MOCVD apparatus, and then the insulating layer 17 made of, for example, SiO₂ is formed by a plasma CVD method (cf. FIG. 2C). An example of the film thickness of the insulating layer is 200 nm. Next, a resist mask patterned by the photolithography method is formed on the surface of the insulating layer 17. By an etching method using a predetermined chemical agent such as buffered hydrofluoric acid, a part of the insulating layer 17 corresponding to a resist opening is removed to form a through-hole 31c (cf. FIG. 2D).

### (Step S4)

Next, the internal electrode 31 is formed in the through-hole 31c (cf. FIG. 2E). Specifically, after an Au/Zn/Au layer is formed as the internal electrode 31 in the through-hole 31c, the resist mask is removed, and annealing is then performed by heating treatment at 420° C. for 10 minutes, for example, thereby forming an ohmic contact between the first contact layer 21 and the Au/Zn/Au layer.

### (Step S5)

As shown in FIG. 2E, the reflective layer 15 and a metal bonding layer 13a are sequentially formed on the top surface of the insulating layer 17. For example, Al/Au is deposited with a predetermined film thickness by the EB vapor deposition apparatus to form the reflective layer 15, and successively, Ti/Au is deposited with a predetermined film thickness to form the metal bonding layer 13a. Note that the reflective layer 15 may be made of the same material as the internal electrode 31 described above.

An example of the film thickness of the reflective layer 15 is Al/Au=5 nm/200 nm. An example of the film thickness of the metal bonding layer 13a is Ti/Au=150 nm/1500 nm. Note that, as described above, a barrier layer may be formed between the reflective layer 15 and the metal bonding layer 13a. An example of the material film of the barrier layer is Ti/Pt=150 nm/300 nm.

### (Step S6)

As illustrated in FIG. 2F, the support substrate 11 different from the growth substrate 3 is prepared. In the present embodiment, a Si substrate that a Si substrate having a (001) plane as one main surface, highly doped with B, and exhibiting conductivity is used. The electric resistivity of the support substrate 11 is preferably less than 10 mΩ·cm (=0.1 mΩ·m).

### (Step S7)

As illustrated in FIG. 2G, a metal bonding layer 13b is formed on the main surface of the support substrate 11. The metal bonding layer 13b can be formed by the same method as the metal bonding layer 13a described above in step S4. Note that, as described above, a barrier layer may be formed between the support substrate 11 and the metal bonding layer 13b.

### (Step S8)

As illustrated in FIG. 2H, the growth substrate 3 and the support substrate 11 are bonded to each other with the metal bonding layer 13 (13a, 13b) interposed therebetween while being pressurized by using, for example, a wafer bonding device. Preferably, the surfaces of the respective metal bonding layers 13 (13a, 13b) are stacked together in a cleaned state. This bonding treatment is performed, for example, at 300° C. and 1 MPa. By this treatment, the metal bonding layer 13a on the growth substrate 3 and the metal bonding layer 13b on the support substrate 11 are melted and integrated (metal bonding layer 13).

### (Step S9)

As illustrated in FIG. 2I, the growth substrate 3 is removed. As an example, the growth substrate 3 is removed by immersing the bonded wafer in a hydrochloric acid-based etchant. At this time, because the ES layer 24 formed of a material different from the growth substrate 3 and the buffer layer 22 is insoluble in a hydrochloric acid-based etchant, the etching treatment is stopped when the ES layer 24 is exposed.

### (Step S10)

As illustrated in FIG. 2J, the ES layer 24 is removed to expose the second cladding layer 27. For example, after cleaning with pure water as necessary, the ES layer 24 is removed by immersion in a predetermined chemical solution soluble in the ES layer 24 and insoluble in the second cladding layer 27. As an example, a mixed solution (SPM) of sulfuric acid and hydrogen peroxide water can be used.

### (Step S11)

As illustrated in FIG. 2K, the top-side electrode 32 is formed on the exposed surface of the second cladding layer 27. Specifically, the following procedure is performed.

A resist mask patterned by the photolithography method is formed on the surface of the second cladding layer 27. Next, after a material for forming the top-side electrode 32 (e.g., Au/Ge/Au) is deposited by the EB vapor deposition apparatus, the lift-off is performed to form the top-side electrode 32. An example of the film thickness of the top-side electrode 32 is Au/Ge/Au=10 nm/30 nm/150 nm.

Next, the pad electrode 34 is formed on the top surface of the top-side electrode 32 at a predetermined position. Similarly to the case of the top-side electrode 32, the formation in this case can also be achieved by the film forming step and the lift-off step by the EB vapor deposition apparatus. As the pad electrode 34, for example, Ti/Pt/Au is deposited, and an example of the thickness thereof is Ti/Pt/Au=150 nm/300 nm/1500 nm.

### (Step S12)

As illustrated in FIG. 2L, the uneven portion 40 is formed on the first surface 27p of the second cladding layer 27.

As an example of a specific method, first, a resist patterned on the first surface 27p of the second cladding layer 27 based on the photolithography method is formed. In this resist, a pattern in which a plurality of holes having a diameter of 3 μm are arranged in a triangular lattice shape with a period length of 6 μm is formed in a region excluding a region where the top-side electrode 32 is formed. Note that the region where the top-side electrode 32 is formed is covered with a resist in which no holes are formed.

Etching is performed on the first surface 27p of the second cladding layer 27 using an etchant such as a hydrochloric acid-phosphoric acid mixed solution via the patterned resist. As a result, an etching pattern having a depth of, for example, 1 μm with respect to the first surface 27p is formed through the holes provided in the resist. Thereafter, the resist is removed with a cleaning liquid such as acetone. Note that the order of step S11 and step S12 may be changed.

### (Step S13)

As illustrated in FIG. 2M, mesa etching for separating each element is performed. Specifically, wet etching is performed using a predetermined etchant while a non-etched region of the surface of the second cladding layer 27 is masked by a resist patterned by the photolithography method. As a result, a part of the first stacked body 20a, a part of the active layer 25, and a part of the second stacked body 20b located in the unmasked region is removed.

As an example of a specific method, first, the second cladding layer 27 is removed by etching using a hydrochloric acid-phosphoric acid mixed solution. This reaction is stopped when the active layer 25 is exposed. Next, the active layer 25 is removed by etching using a mixed solution of sulfuric acid and hydrogen peroxide water (SPM). This reaction is stopped in the first cladding layer 23. Next, the first cladding layer 23 and the first contact layer 21 are removed by etching using the hydrochloric acid-phosphoric acid mixed solution, and the insulating layer 17 is exposed. Thereafter, the resist is removed by a cleaning liquid such as acetone.

### (Step S14)

As illustrated in FIG. 2N, a protection film 29 also functioning as an antireflection film is formed on the exposed surfaces of the first stacked body 20a, the active layer 25, and the second stacked body 20b by the plasma CVD method. After the film formation, the pad electrode portion forms an opening pattern using the photolithography method, and the pad electrode 34 is exposed by an etching method using a predetermined chemical liquid such as buffered hydrofluoric acid. Thereafter, the resist is removed using an organic solvent such as acetone.

### (Step S15)

After the thickness on the back surface side of the support substrate 11 is adjusted, the back-side electrode 33 is formed on the back surface side of the support substrate 11 (cf. FIG. 1). As a specific method of forming the back-side electrode 33, similarly to the top-side electrode 32, the back-side electrode 33 can be formed by depositing a material (e.g., Ti/Pt/Au) for forming the back-side electrode 33 by a vacuum vapor deposition apparatus. An example of the film thickness of the back-side electrode 33 is Ti/Pt/Au=150 nm/300 nm/1500 nm. After the formation of the back-side electrode, heat treatment is performed at 250° C. for 10 minutes to improve the adhesion between the top-side electrode and the pad electrode and stabilize the ohmic characteristics between the back-side electrode and the support substrate.

A method of adjusting the thickness of the support substrate 11 is optional, but as an example, a method of grinding with a back grinder in a state where the second stacked body 20b side is attached to a back grind tape can be employed. The thickness after the grinding is adjusted, for example, within a range of 50 μm to 250 μm, and is appropriately selected according to the application of the infrared LED element 1 and the subsequent process. As a specific example, the thickness of the support substrate 11 after the grinding is 150 μm. After the grinding processing is completed, the tape is peeled off and the substrate is cleaned.

Note that the adjustment of the thickness on the back surface side of the support substrate 11 may be performed as necessary, and is not necessarily an essential step.

### (Step S16)

Next, the support substrate 11 is diced together to form chips. For example, in a state where the back-side electrode 33 side is attached with a dicing tape, dicing is performed together with the support substrate 11 from the top-side electrode 32 side along a dicing line formed by the mesa etching in step S13, by using a diamond blade or the like.

Thereafter, the chipped infrared LED element 1 is mounted on a stem or the like using a conductive adhesive such as an Ag paste. The pad electrode 34 is connected to a post portion of the stem by wire bonding.

### Verification Experiment 1

Here, verification experiments were conducted to confirm the relationship between the peak wavelength of the emitted light and the driving voltage (forward voltage) of the infrared LED element for the infrared LED element 1, and the details will be described below.

### (Samples)

Examples, Comparative Examples, and Reference Examples were as shown in Table 1 below. Note that Table 1 shows that the respective elements of Comparative Examples 1 to 4 and Reference Examples 3 to 7 do not include an intermediate layer (23a, 27a).

TABLE 1

| | Peak | | Intermediate layer |
|---|---|---|---|
| Sample | wavelength | Peak wavelength | band gap energy |
| Example 1 | 1450 nm | Ga_{0.19}In_{0.81}As_{0.42}P_{0.58} | 1.07 eV |
| Example 2 | 1550 nm | Ga_{0.22}In_{0.78}As_{0.48}P_{0.52} | 1.03 eV |
| Example 3 | 1650 nm | Ga_{0.28}In_{0.72}As_{0.61}P_{0.59} | 0.95 eV |
| Example 4 | 1750 nm | Ga_{0.28}In_{0.72}As_{0.61}P_{0.59} | 0.95 eV |
| Example 5 | 1900 nm | Ga_{0.28}In_{0.72}As_{0.61}P_{0.59} | 0.95 eV |
| Comparative | 1450 nm | — | — |
| Example 1 | | | |
| Comparative | 1550 nm | — | — |
| Example 2 | | | |
| Comparative | 1650 nm | — | — |
| Example 3 | | | |
| Comparative | 1750 nm | — | — |
| Example 4 | | | |
| Reference | 1200 nm | Ga_{0.11}In_{0.89}As_{0.25}P_{0.75} | 1.18 eV |
| Example 1 | | | |
| Reference | 1300 nm | Ga_{0.15}In_{0.85}As_{0.33}P_{0.67} | 1.13 eV |
| Example 2 | | | |
| Reference | 1050 nm | — | — |
| Example 3 | | | |
| Reference | 1100 nm | — | — |
| Example 4 | | | |
| Reference | 1150 nm | — | — |
| Example 5 | | | |
| Reference | 1200 nm | — | — |
| Example 6 | | | |
| Reference | 1300 nm | — | — |
| Example 7 | | | |

### (Measurement Method)

The value of the driving voltage (forward voltage Vf) applied between the anode terminal and the cathode terminal of the sample was measured such that the current (supply current If) supplied to the sample was 100 mA.

### (Results)

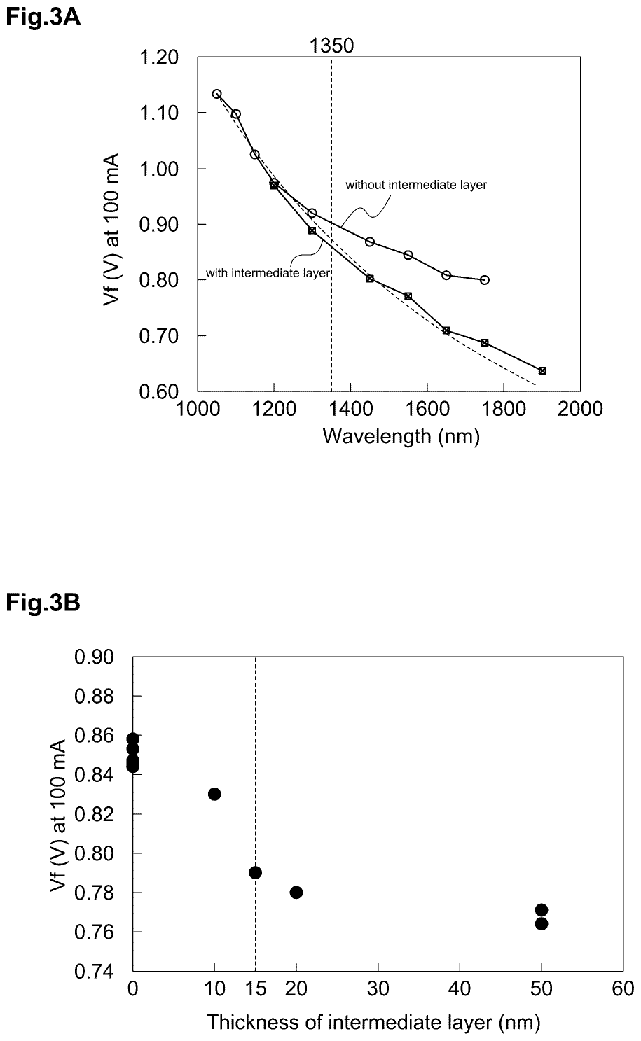

FIG. 3A is a graph obtained by plotting the results of Verification Experiment 1. Note that, in FIG. 3A, a quadrangular plot illustrates a plot of a sample (Examples 1 to 5, Reference Examples 1 and 2) including the intermediate layer (23a, 27a), and a circular plot illustrates a plot of a sample (Comparative Examples 1 to 4, Reference Examples 3 to 7) not including the intermediate layer (23a, 27a). Note that, in the graph of FIG. 3A, a curve of a theoretical forward voltage calculated based on the band gap energy Eₐ of the active layer is indicated by a broken line.

Here, as described above, the theoretical forward voltage was derived based on the relationship between the energy E and the wavelength λ (E (eV)=hc/2=1240/2) based on a forward voltage Vf₁₀₅₀ of the infrared LED element having a peak wavelength of 1050 nm. Note that h is a Planck constant, and c is the speed of light. More specifically, when the peak wavelength is λₓ and the magnitude of the voltage drop with respect to the forward voltage Vf₁₀₅₀ of the infrared LED element having the peak wavelength of 1050 nm is ΔVf, Vf=Vf₁₀₅₀−ΔVf (λₓ)=Vf₁₀₅₀−(1240/1050−1240/λₓ) is derived.

As illustrated in FIG. 3A, for samples with a peak wavelength below 1350 nm, it is confirmed that the forward voltage Vf is sufficiently close to the theoretical curve, regardless of the presence or absence of the intermediate layer. In contrast, for samples with a peak wavelength of 1350 nm or more, differences in forward voltage Vf appears depending on the presence or absence of the intermediate layer, and in Comparative Examples 1 to 4 without intermediate layer, it is confirmed that the forward voltage Vf is largely separated from the theoretical curve as the peak wavelength is on the longer wavelength side, and in Examples 1 to 5 with the intermediate layer, the forward voltage Vf is close to the theoretical curve regardless of the peak wavelength.

### Verification Experiment 2

Next, for the infrared LED element 1, a verification experiment for confirming the relationship between the thickness of the first intermediate layer 23a and the driving voltage (forward voltage) of the infrared LED element has been performed, and details thereof will be described below.

### (Samples)

As experimental samples, samples were prepared with the thickness of first intermediate layer 23a set to 0 nm (4 pieces), 10 nm (1 piece), 15 nm (1 piece), 20 nm (1 piece), or 50 nm (2 pieces). Note that each of the samples was an infrared LED element in which the peak wavelength of emitted light was 1550 nm.

### (Measurement Method)

The value of the driving voltage (forward voltage Vf) applied between the anode terminal and the cathode terminal of the sample was measured such that the current (supply current If) supplied to the sample was 100 mA.

### (Results)

FIG. 3B is a graph obtained by plotting the results of Verification Experiment 2. As illustrated in FIG. 3B, it can be confirmed that the forward voltage Vf rapidly drops when the thickness of each of the intermediate layers (23a, 27a) is 15 nm or more.

As described above, in the infrared LED element 1 having the above configuration, even when the active layer 25 is a layer that emits light having a peak wavelength of 1350 nm or more, the driving voltage (forward voltage) is sufficiently close to a value theoretically derived by providing the first intermediate layer 23a. That is, in the infrared LED element 1 having the above configuration, the forward voltage is reduced compared to the conventional infrared LED element, and as a result, the light emission efficiency is improved.

### Other Embodiments

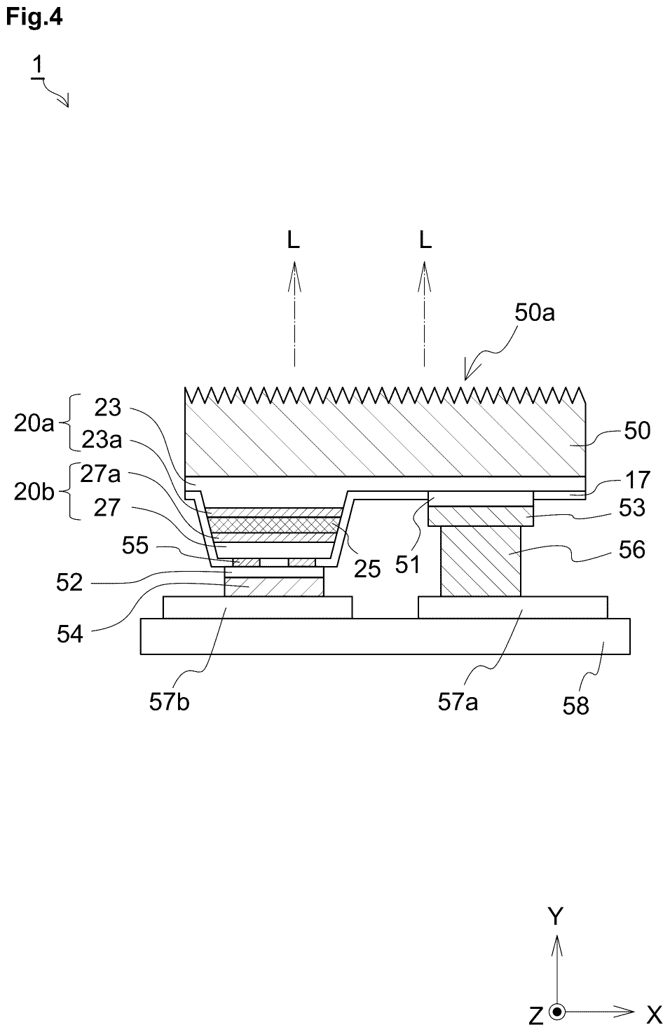

Other embodiments will now be described.

<1> FIG. 4 is a cross-sectional view schematically illustrating a structure of an infrared LED element 1 according to another embodiment. As illustrated in FIG. 4, the infrared LED element 1 of the present embodiment includes an InP substrate 50, a first stacked body 20a, an active layer 25, a second stacked body 20b, an insulating layer 17, reflective electrodes (51, 52) corresponding to reflective layers, a first electrode 53, a second electrode 54, an internal electrode 55, and a height adjustment electrode 56.

The InP substrate 50 is a growth substrate, and the surface thereof constitutes a light-emitting surface 50a for extracting the infrared light L. As illustrated in FIG. 4, the light-emitting surface 50a is formed with an uneven portion as in the embodiment described above.

As in the embodiment described above, the first stacked body 20a, the active layer 25, and the second stacked body 20b have a structure in which the first cladding layer 23, the first intermediate layer 23a, the active layer 25, the second intermediate layer 27a, and the second cladding layer 27 are stacked. In the first stacked body 20a of the present embodiment, when viewed in the Y direction, the first cladding layer 23 is formed over the entire InP substrate 50, but the first intermediate layer 23a, the active layer 25, the second intermediate layer 27a, and the second cladding layer 27 are formed only on a part of the InP substrate 50. Here, in another embodiment, the first cladding layer 23 corresponds to the “first semiconductor layer”, the second cladding layer 27 corresponds to the “second semiconductor layer”, and the first intermediate layer 23a corresponds to the “intermediate layer”.

The reflective electrodes (51, 52) each correspond to a reflective layer that reflects infrared light L emitted from the active layer 25 and traveling to the insulating layer 17 side (−Y side) by repeating reflection directly or in the element so as to travel to the InP substrate 50 side (+Y side). The flip-chip infrared LED element 1 as in the present embodiment is flip-mounted on a submount 58 as described above.

The first electrode 53 is provided to be electrically connected to a region of the first cladding layer 23 on or over which the first intermediate layer 23a is not disposed, and the second electrode 54 is provided to be in contact with the surface of the reflective electrode 52 on a side opposite to a side where the insulating layer 17 is formed (−Y side).

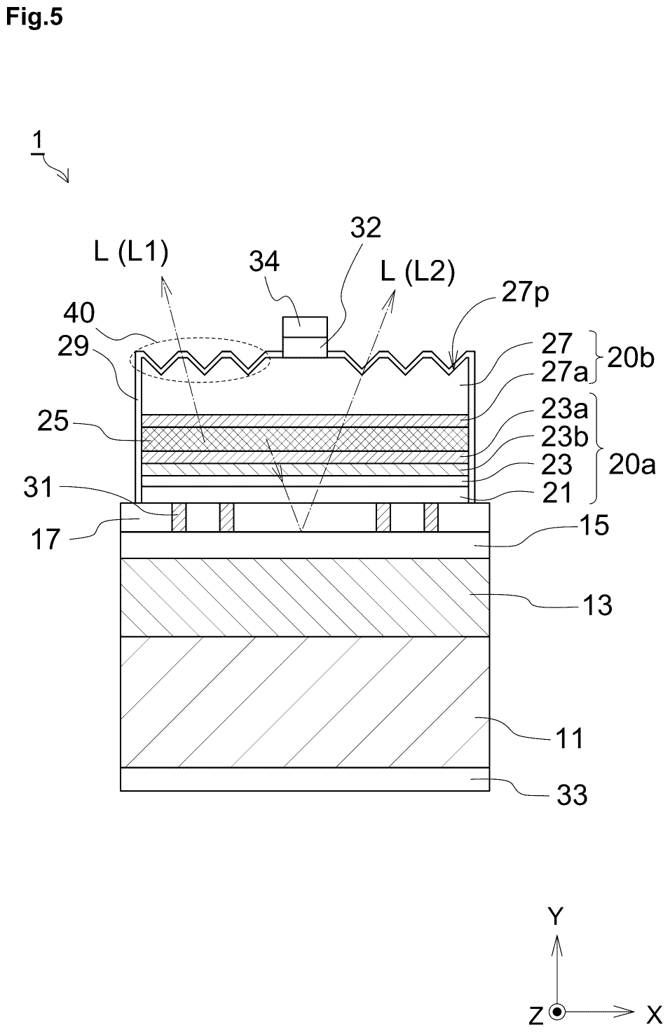

The insulating layer 17 is disposed to connect side surfaces of the first stacked body 20a, the active layer 25, and the second stacked body 20b, the top surface of the second cladding layer 27, and the top surface of the first cladding layer 23 in a region on or over which the first intermediate layer 23a is not disposed.

<2> FIG. 5 is a cross-sectional view schematically illustrating a structure of an infrared LED element 1 according to another embodiment different from that in FIG. 4. As illustrated in FIG. 5, the first stacked body 20a may include an electron blocking layer 23b on the +Y side of the first cladding layer 23 and on the −Y side of the first intermediate layer 23a. The electron blocking layer 23b is made of, for example, AlInAs.

<3> In each of the embodiments described above, an aspect has been described in which the first intermediate layer 23a and the second intermediate layer 27a are both provided, but at least one of the intermediate layers may be provided.

<4> In the embodiments described above, the first stacked body 20a (first contact layer 21, first intermediate layer 23a, and first cladding layer 23) is a p-type semiconductor, and the second stacked body 20b (second intermediate layer 27a and second cladding layer 27) is an n-type semiconductor. However, the conductivity types of the first semiconductor layer and the second semiconductor layer may be reversed. The intermediate layer (first intermediate layer 23a and second intermediate layer 27a) may be undoped.

<5> The configurations included in the infrared LED element 1 described above are merely examples, and the present invention is not limited to the illustrated configurations.

What is claimed is:

1. An infrared light-emitting diode (LED) element capable of emitting infrared light having a peak wavelength of 1350 nm to 2000 nm, the infrared LED element comprising:
a first stacked body including a first semiconductor layer and an intermediate layer in a stacking direction, the first semiconductor layer exhibiting a first conductivity type that is one of n-type or p-type, the intermediate layer having a thickness of 15 nm or more;
an active layer disposed on or over the intermediate layer of the first stacked body; and
a second stacked body including a second semiconductor layer that exhibits a second conductivity type different from the first conductivity type and is disposed on or over the active layer, wherein
a relationship Eₐ<Eₘ<Eₚ holds, where Eₐ represents band gap energy of the active layer, Eₘ represents band gap energy of the intermediate layer, and Eₚ represents band gap energy of the first semiconductor layer.

2. The infrared LED element according to claim 1, wherein the active layer is formed by stacking a well layer and a barrier layer, and a relationship Eₐ<E_{b}<Eₘ holds, where E_{b} represents band gap energy of the barrier layer.

3. The infrared LED element according to claim 1, wherein the intermediate layer is a semiconductor layer having a dopant concentration of 2×10¹⁸/cm³ or less.

4. The infrared LED element according to claim 1, wherein the active layer has a thickness of 30 nm or more.

5. The infrared LED element according to claim 1, wherein the first semiconductor layer is made of InP.

6. The infrared LED element according to claim 1, wherein the active layer is made of GaInAsP.

7. The infrared LED element according to claim 1, wherein the first stacked body includes an electron blocking layer made of AlInAs and disposed on or over the first semiconductor layer.

8. The infrared LED element according to claim 1, wherein, when a difference between the band gap energy Eₐ of the active layer and the band gap energy Eₚ of the first semiconductor layer is 100%, a difference between the band gap energy Eₐ of the active layer and the band gap energy Eₘ of the intermediate layer is within a range of 30% to 60%.

9. The infrared LED element according to claim 2, wherein the intermediate layer is a semiconductor layer having a dopant concentration of 2×10¹⁸/cm³ or less.

10. The infrared LED element according to claim 2, wherein the active layer has a thickness of 30 nm or more.

11. The infrared LED element according to claim 2, wherein the first semiconductor layer is made of InP.

12. The infrared LED element according to claim 2, wherein the active layer is made of GaInAsP.

13. The infrared LED element according to claim 2, wherein the first stacked body includes an electron blocking layer made of AlInAs and disposed on or over the first semiconductor layer.

14. The infrared LED element according to claim 2, wherein, when a difference between the band gap energy Eₐ of the active layer and the band gap energy Eₚ of the first semiconductor layer is 100%, a difference between the band gap energy Eₐ of the active layer and the band gap energy Eₘ of the intermediate layer is within a range of 30% to 60%.
